(19) United States
(12) Patent Application Publication
(10) Pub. No.: US 2007/0176123 A1
(43) Pub. Date: Aug. 2, 2007

(54) Ion implanter having a superconducting magnet

(75) Inventors: Leonard M. Rubin, S. Hamilton, MA (US); John M. Poate, Boulder, CO (US)

Correspondence Address: TAROLLI, SUNDHELM, COVELL & TUMMINO, LLP, 1300 EAST NINTH STREET, SUITE 1700, CLEVELAND, OH, 44114, US

(73) Assignee: Axcelis Technologies, Inc.

(21) Appl. No.: 11/343,760

(22) Filed: Jan. 31, 2006

(51) Int. Cl. H01J 37/317

(52) U.S. Cl. 250/492.21

(57) ABSTRACT

An ion beam implanter includes an ion beam source for generating an ion beam moving along a beam line and a vacuum or implantation chamber wherein a workpiece, such as a silicon wafer is positioned to intersect the ion beam for ion implantation of a surface of the workpiece by the ion beam. Various magnets located along the beamline are provided for manipulating the ion beam and ions. Ion beam implanters having magnets including superconducting magnet coils are disclosed.

### FIELD OF THE INVENTION

The present invention concerns ion implanters and more particularly an ion implanter having an analyzer magnet and/or other magnet structure for use in providing an ion beam to implant ions into a workpiece.

### BACKGROUND ART

Axcelis Technologies, assignee of the present invention, designs and sells products for treatment of workpieces such as silicon wafers during integrated circuit fabrication. Ion implanters create an ion beam that modifies the physical or electrical properties of workpieces such as silicon wafers that are placed into the ion beam. This process can be used, for example, to dope the silicon from which the untreated wafer is made to change the properties of the semiconductor material. Controlled use of masking with resist materials prior to ion implantation, as well as layering of different dopant patterns within the wafer, produce an integrated circuit for use in one of a myriad of applications.

An ion implantation chamber of an ion beam implanter is maintained at reduced pressure. Subsequent to acceleration along a beam line, the ions in the beam enter the implantation chamber and strike the wafer. In order to position the wafer within the ion implantation chamber, wafers are moved by a robot into a load lock from a cassette or storage device that is located at high pressure.

### SUMMARY OF THE INVENTION

The present invention concerns an ion beam implanter for implanting a workpiece such as a semiconductor wafer. The ion beam implanter includes an ion beam source for generating an ion beam moving along a path of travel directed toward a workpiece. The beam can be delivered to the wafer as a so called “pencil beam”, can be scanned back and forth from an initial trajectory in a raster scan manner, or can be generated as a so-called “ribbon beam”. A workpiece support positions a wafer in an implantation chamber so that the ions that make up the beam strike the workpiece.

An exemplary ion beam implanter includes an ion source for generating an ion beam confined to a beam path and an implantation chamber having an evacuated interior region wherein a workpiece is positioned to intersect the ion beam. The implanter further includes at least one magnet positioned along the beam path between the ion source and the implantation chamber including i) a core material and ii) a superconducting magnet conductor positioned relative to said core material which, when energized creates a magnetic field for bending the ions in the ion beam away from an initial trajectory at which they enter the magnet

Superconducting magnets have several advantages over conventional magnets used in prior art ion implanters. These include, but are not limited to: decreased size, weight, and power consumption; increased temporal and spatial stability of the resulting magnetic field; and ability to produce uniform magnetic fields over a wide area, which may be an enabling technology for steering a “ribbon” beam wide enough to uniformly implant wafers with a diameter as wide as 300 mm, and possibly as high as the 450 mm and 700 mm diameters that are currently being projected for implant technology roadmaps. Superconducting magnets may also be advantageously used to mass analyze high mass species such as In or Sb at extraction energies higher than possible with prior art magnet technology. In addition, superconducting magnets may provide valuable benefits in scanned beam architectures where scanning and parallelizing magnets are utilized along the path of beam travel.

These and other features of the exemplary embodiment of the invention are described in detail in conjunction with the accompanying drawings.

### BRIEF DESCRIPTION OF THE DRAWINGS

FIG. 1 is a schematic plan view of an ion beam implanter in accordance with at least one aspect of the present invention;

FIG. 2 is a perspective view of an additional magnet in accordance with the present invention for use with an ion beam implanter;

FIG. 3 is a top view of an alternate ion beam implanter architecture that could incorporate the present invention, including a rotating workpiece support; and

FIG. 4 is a perspective view showing a bottom half of a scanning magnet constructed in accordance with one exemplary embodiment of the invention.

### EXEMPLARY MODE FOR PRACTICING THE INVENTION

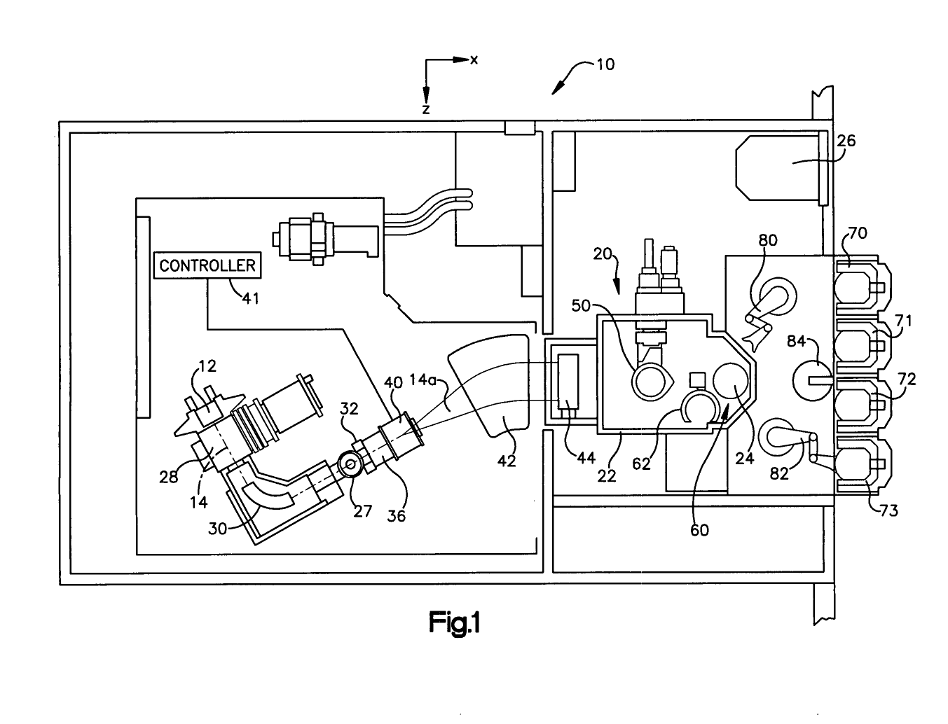

Turning to the drawings, FIG. 1 illustrates a schematic depiction of an ion beam implanter 10. The implanter includes an ion source 12 for creating ions that form an ion beam 14, which is shaped and selectively deflected to traverse a beam path to an end or implantation station 20. The implantation station includes a vacuum or implantation chamber 22 defining an interior region in which a workpiece 24 such as a semiconductor wafer is positioned for implantation by ions that make up the ion beam 14. Control electronics indicated schematically as controller 41 are provided for monitoring and controlling the ion dosage received by the workpiece 24. Operator input to the control electronics are performed via a user control console 26 typically located near the end station 20. The ions in the ion beam 14 tend to diverge undesirably as the beam traverses a region between the source and the implantation chamber. To reduce this divergence, the region is maintained at low pressure by one or more vacuum pumps 27.

The ion source 12 includes a plasma chamber defining an interior region into which source materials including an ionizable gas or vaporized source material are injected. Ions generated within the plasma chamber are extracted from the chamber by ion beam extraction assembly 28, which typically includes a number of electrodes for creating an ion accelerating electric field.

Positioned along the beam path is an analyzing magnet 30 having superconducting electromagnetic coils, which when energized bend the ion beam 14 and direct it through a beam shutter 32. As illustrated in FIG. 1, downstream of the beam shutter 32, the beam 14 passes through a quadrupole lens system 36, which may be provided in a typical ion implantation system for focusing the beam 14. In accordance with the scanned ion beam architecture illustrated in FIG. 1, the beam then passes through a scanning or deflection magnet 40, which is controlled by the controller 41. The controller 41 provides an alternating current signal to the conductive windings of the magnet 40 which in turn causes the ion beam 14 to repetitively deflect or scan from side to side at a frequency of several hundred Hertz. In one disclosed embodiment, scanning frequencies of from 200 to 300 Hertz are used. This deflection or side to side scanning generates a thin, fan-shaped beam, depicted as ion beam 14a.

Ions within the fan-shaped beam follow diverging paths along a single plane after they leave the scanning magnet 40. Thereafter, the ions typically enter a parallelizing magnet 42, wherein the ions that make up the beam 14a are again bent by varying amounts so that they exit the parallelizing magnet 42 moving along generally parallel beam paths. Those of skill in the art will recognize that the ions may be directed to enter magnetic structure shown as an energy filter 44 that deflects the ions in a direction transverse to the scan plane, in a downward or upward direction relative to the y-axis direction shown in FIG. 1. This angular deflection removes neutral particles that may have entered the beam during the upstream beam shaping and transport. It will be understood that the superconducting magnet concept of the present invention may be incorporated into any of the magnetic structures described herein for manipulating ions and ion beams to provide preferred shaping and transport of the ion beam to its ultimate destination, the workpiece.

The scanned ion beam 14a that exits the parallelizing magnet 42 is an ion beam with a cross-section essentially forming a very narrow rectangle, that is, a beam that extends in one direction, e.g., has a vertical extent that is limited (e.g. approx ½ inch) and has an extent in the orthogonal direction that widens outwardly due to the scanning or deflecting caused by the scanning magnet 40 to completely cover a diameter of a workpiece such as a silicon wafer. Generally, the extent of the scanned ion beam 14a is sufficient, when scanned, to implant an entire surface of the workpiece 24. That is, the scanning magnet 40 will deflect the beam such that a horizontal extent of the scanned ion beam 14a, upon striking the implantation surface of the workpiece 24 within the implantation chamber 22, will be at least the diameter of the workpiece.

A workpiece support structure 50 both supports and moves the workpiece 24 (up and down in the y direction) with respect to the scanned ion beam 14 during implantation such that an entire implantation surface of the workpiece 24 is uniformly implanted with ions. Since the implantation chamber interior region is evacuated, workpieces must enter and exit the chamber through a loadlock 60. A robotic arm 62 mounted within the implantation chamber 22 automatically moves wafer workpieces to and from the loadlock 60. A workpiece 24 is shown in a horizontal position within the load lock 60 in FIG. 1. The arm moves the workpiece 24 from the load lock 60 to the support 50 by rotating the workpiece through an arcuate path. Prior to implantation, the workpiece support structure 50 rotates the workpiece 24 to a vertical or near vertical position for implantation. If the workpiece 24 is vertical, that is, normal with respect to the ion beam 14, the implantation angle or angle of incidence between the ion beam and the normal to the workpiece surface is 0 degrees.

In a typical implantation operation, undoped workpieces (typically semiconductor wafers) are retrieved from one of a number of cassettes 70-73 by one of two robots 80, 82 which move a workpiece 24 to an orienter 84, where the workpiece 24 is rotated to a particular orientation. A robot arm retrieves the oriented workpiece 24 and moves it into the load lock 60. The load lock closes and is pumped down to a desired vacuum, and then opens into the implantation chamber 22. The robotic arm 62 grasps the workpiece 24, brings it within the implantation chamber 22 and places it on the workpiece support structure 50. After ion beam processing of the workpiece 24, the workpiece support structure 50 returns the workpiece 24 to a horizontal position and the electrostatic clamp is de-energized to release the workpiece. The arm 62 grasps the workpiece 24 after such ion beam treatment and moves it from the support 50 back into the load lock 60. In accordance with an alternate design the load lock has a top and a bottom region that are independently evacuated and pressurized and in this alternate embodiment a second robotic arm (not shown) at the implantation station 20 grasps the implanted workpiece 24 and moves it from the implantation chamber 22 back to the load lock 60 and into one of the cassettes 70-73.

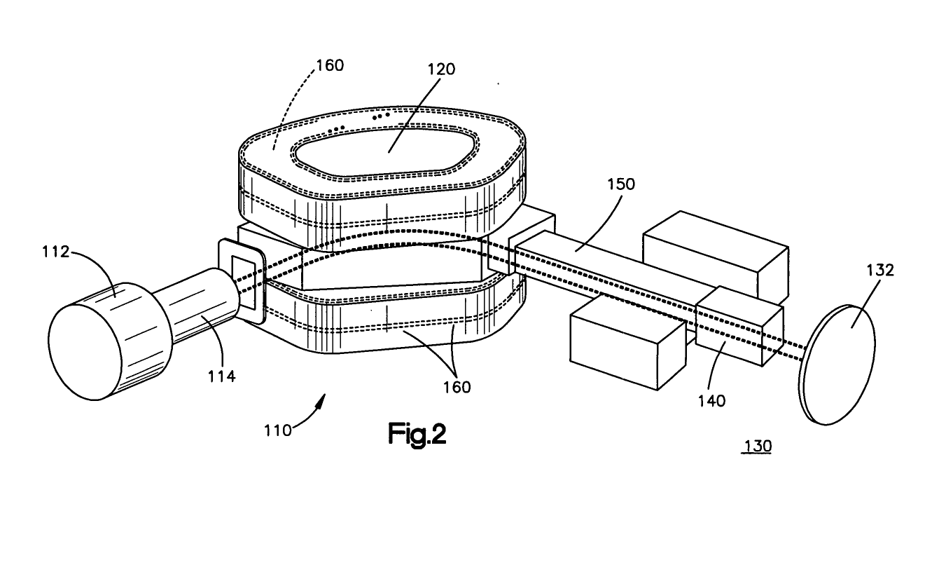

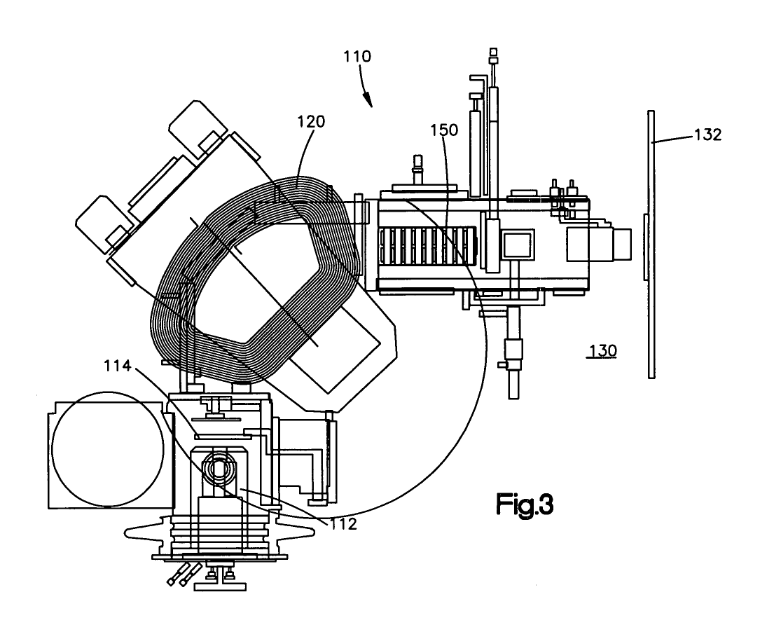

FIGS. 2 and 3 schematically depict an ion implanter 110 having architecture that differ from the ion implanter of FIG. 1, for transporting a ribbon beam (FIG. 2), or pencil beam (FIG. 3) to the workpiece. These ion implanter architectures 110 includes a source 112 for generating ions, an extraction electrode structure 114 for accelerating the ions emitted by the source and a mass analysis magnet 120 for bending ions of the proper charge to mass ratio along trajectories for entering an ion implantation chamber 130 having a wafer support 132 that may include a spinning disk or other support system for moving a single wafer or multiple wafers through the ion beam 140. The ions that make up the beam may be accelerated toward the wafer by a draft tube or a linear accelerator 150 which accelerates ions following a proper trajectory as they exit the magnet 120 to impact wafers on the support with a proper wafer treatment energy.

Superconducting Magnet Materials

The various magnets typically used in an ion implantation system, including, but not limited to the exemplary mass analysis magnet 30, scanning magnet 40, parallelizing magnet 42 and/or angular energy deflection magnet 44 described herein above with respect to the implantation system of FIG. 1 as well as the mass analysis magnet 120 of FIGS. 2 and 3 are magnets that can be made with electromagnetic field generating coils of a superconducting material. In the world of superconducting materials, a key characterizing parameter is the so-called critical temperature (T_{C}) of the material, which refers to the maximum temperature at which a given material becomes superconducting. Preferably, these superconducting coils are made with either low T_{C} materials (e.g. NbTi) or a newer (high Tc) material (e.g. Bi₂Sr₂CaCu₂O₈), approximately 85 degrees K. A third superconducting material for use in the magnet coil is magnesium diboride MgB₂, which is a high T_{C} material. Closed cycle refrigeration using liquid nitrogen and/or liquid helium is used to cool the superconducting magnets. The beam steered by these magnets could be either a fixed “pencil” beam (FIGS. 2 and 3), a scanned pencil beam (FIG. 1), or a fixed “ribbon” beam (not shown). The endstation downstream from the magnet can process either one wafer or workpiece at a time or a batch or multiple wafers at a time. A presently preferred superconducting material is magnesium diboride which is more malleable and hence easier to fabricate into the shape of a current conducting coil.

In an exemplary embodiment of a mass analyzing magnet in accordance with the present invention, as shown in FIG. 2, the coils 160 making up the magnet are a series of stacked loops defining the shape of the magnet. The loops are not circular, but conform to the (existing) outline of the region of the magnet of which they are part. The loops are thicker than the gaps between them. There are ˜2-4 loops total around the thickness of the top of the magnet (and the same number on the bottom) and the loops extend directly above and below the beam entrance and exit of the magnet.

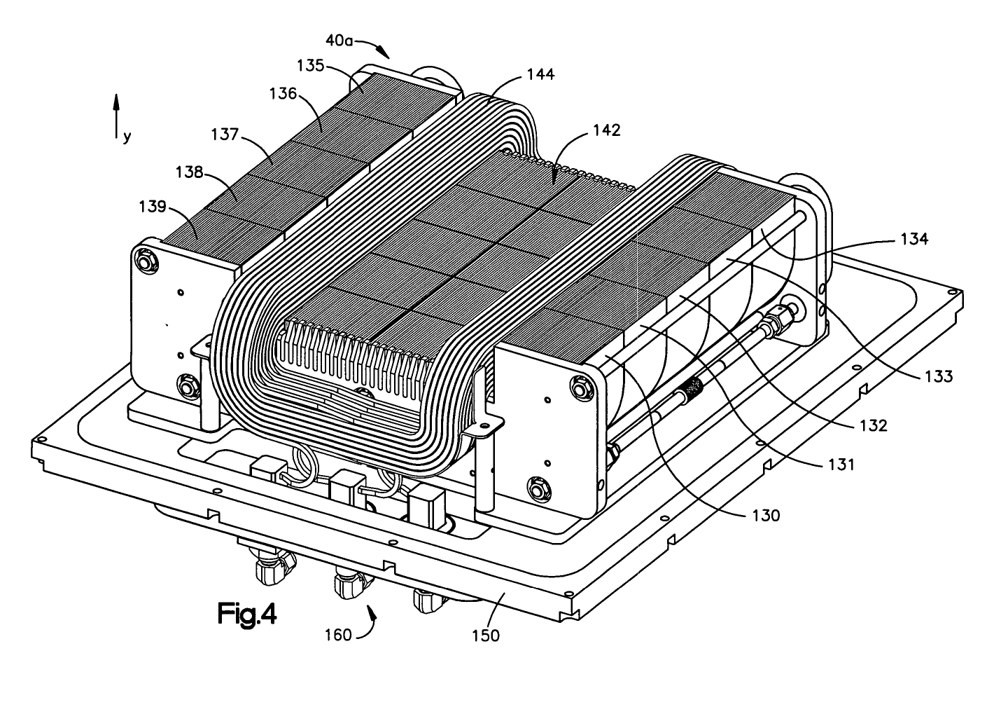

FIG. 4 illustrates in greater detail the structure of the scanning magnet 40 of FIG. 1. The magnet is an electromagnet having a core 142, including yoke and pole pieces constructed from a ferromagnetic material. A magnetic field is induced in the pole gap of the magnet through controlled electrical energization of superconducting current carrying conductors or coils 144.

In combination with the conductors 144, two core portions are situated in face-to-face orientation to form a magnet entrance so that ions enter a center passageway of the magnet. A singular bottom section of the core 40a is depicted in FIG. 4, and may be made up of several sections 130-139, as in the illustrated embodiment. In the illustrated embodiment, the core is constructed from five ribbon windings which are each cut in two places to provide two sections (such as 130, 139) of the magnet core. With respect to the illustrated embodiment, ten core sections are situated having five core sections on each side (symmetric with respect to a magnet centerline) with the longer prong of each “U” shaped section to the outer side of the magnet. When paired with a similar core in face-to face-orientation, this configuration creates two channels on each side of the center passageway. In the preferred embodiment, the conductors 144 are situated in these channels, in a so-called saddle coil configuration.

Each of the core sections is made up of many individual magnet laminations which are generally thin, planar sheets or ribbons that are wound about a mandrel to form the magnet sections. The exposed planar surface of the center segment of the overall core is made up of a combination of the cut ends of the smaller prongs of each of the ten “U” shaped core sections.

The two halves of the magnet yoke (all ten core sections in the exemplary embodiment) are supported by structure above and below the beamline passageway that includes mounting flanges 150 that support the yoke and saddle coils. In accordance with the present invention, the saddle coils are constructed from hollow superconducting materials through which a coolant fluid is routed during operation of the magnet. The core and coils are supported by flange 150. As seen in FIG. 4, the flange 150 also supports a manifold 160 for receiving cooling fluid (such as liquid nitrogen or liquid helium) and for routing heated fluid away from the magnet. A similar manifold located on a top flange performs these functions for the top half of the magnet. The manifold 160 delivers coolant through hoses (not shown) to couplings (not shown) of the magnet 40. A suitable refrigeration system and pump would be included in both the FIG. 1 and FIG. 3 implanters to provide a sustainable supply of such coolant.

In operation, control electronics coupled to the magnet coils energize the coils to create an alternating magnetic field that deflects the ions entering the magnet by a varying amount that depends on the instantaneous field strength when the ion enters the magnet. The magnetic field has a vector component in generally the positive y direction with one polarity of coil energization and a vector component in generally the negative y direction with the second polarity electrical energization.

While the present invention has been described with a degree of particularity, it is the intent that the invention includes all modifications and alterations from the disclosed design falling with the spirit or scope of the appended claims.

We claim:

1. An ion beam implanter comprising:
a) an ion source for generating an ion beam;
b) an implantation chamber having an evacuated interior region wherein a workpiece is positioned to intersect the ion beam; and
c) a magnet positioned along a path between said ion source and said implantation chamber, said magnet including
i) a core material and
ii) a superconducting coil material positioned relative to said core material which, when energized creates a magnetic field for bending the ions in the ion beam away from an initial trajectory at which they enter the magnet.

2. The ion beam implanter of claim 1 wherein the superconducting material wound about the core material is made from a low T_{C} material.

3. The ion beam implanter of claim 2, wherein the low T_{C} superconducting material includes NbTi.

4. The ion beam implanter of claim 1 wherein the superconducting material wound about the core material is made from a high T_{C} material.

5. The ion beam implanter of claim 4 wherein the high T_{C} superconducting material includes magnesium diboride.

6. The ion beam implanter of claim 4 wherein the high T_{C} superconducting material includes Bi₂Sr₂CaCu₂O₈.

7. The ion beam implanter of claim 1 wherein the superconducting material is wound into a coil and includes a passageway for routing a coolant through at least some portion of said coil.

8. A mass analysis magnet for use in an ion beam implanter, the magnet having a core comprising a ferromagnetic core material and a superconducting coil for setting up a magnetic field for selectively deflecting the ion beam from its original trajectory.

9. A scanning magnet for use in an ion beam implanter, the magnet having a core comprising a ferromagnetic core material and a superconducting coil for setting up a magnetic field to scan the ion beam in an oscillatory manner.

10. A parallelizing magnet for use in an ion beam implanter, the magnet having a core comprising a metal material and a superconducting material for setting up a magnetic field to bend ions in the ion beam by varying amounts so that they exit the parallelizing magnet moving along generally parallel beam paths.

11. An angular deflection magnet for use in an ion beam implanter, the magnet having a core comprising a metal material and a superconducting material for setting up a magnetic field for deflecting the ion beam in a direction transverse to a scan plane thereof.

12. An ion implantation system comprising:
a) an ion source adapted to produce an ion beam along a path for treating a workpiece;
b) an implantation region spaced from said ion source having an interior region for positioning a workpiece at a location for treatment from said ion beam; and
c) a beam guide located between said ion source and said implantation region comprising a magnet having a core material and electromagnetic field generating coils wound about said core material that when energized parallelizes said ion beam, forming a plurality of substantially parallel ion beam paths for treating a workpiece, wherein said electromagnetic field generating coils are made from superconducting materials.

13. The ion implantation system of claim 12, wherein said superconducting materials wound about the core material is made from a low T_{C} material.

14. The ion implantation system of claim 12, wherein said superconducting materials wound about the core material is made from a high T_{C} material.

15. The ion implantation system of claim 14, wherein said high T_{C} material is made from Bi₂Sr₂CaCu₂O₈.

16. The ion implantation system of claim 13, wherein said low T_{C} material is made from NbTi.

17. A method for ion implantation comprising:
a) providing an ion source for generating an ion beam along a first trajectory;
b) orienting a workpiece at a target location of said ion beam within an implantation region; and
c) changing the characteristics of said ion beam to form a second trajectory by directing said ion beam through a magnet having electromagnetic coils made from superconducting material.

18. The method of ion implantation of claim 17, wherein said changing the characteristics of the ion beam includes parallelizing said beam to form a plurality of substantially parallel ion beam paths for treating a workpiece.

19. The method of ion implantation of claim 17, wherein said changing the characteristics of the ion beam includes bending a portion of the beam having ions of proper charge to mass ratio to form a refined ion beam for treating a workpiece.

20. The method of ion implantation of claim 17, wherein said changing the characteristics of the ion beam includes deflecting said beam causing a repetitive scan pattern to occur for treating a workpiece.

21. A method for controlling an ion beam during the implanting of a workpiece comprising the steps of:
a) directing a beam of ions to move along an initial trajectory;
b) causing the beam of ions from the initial trajectory to bend to a second trajectory by passing the beam through an analyzing magnet;
c) focusing the beam of ions by directing the second trajectory through a lens;
d) passing the beam of ions from the second trajectory through a deflecting magnet that when energized causes the beam of ions to scan in a back and forth manner creating a ribbon shaped ion beam;
e) generating a substantially parallel beam path in said ribbon shaped ion beam by directing the ribbon shaped ion beam through a parallelizing magnet; and
f) producing a controlled magnetic field in a region by using a superconducting magnet in any of said analyzing, deflecting, and parallelizing magnets, wherein said superconducting magnet includes a core surrounded by electromagnetic field generating coils made with superconducting materials.

22. An ion beam implantation system having superconducting magnets for steering the ion beam, the system comprising:
a) an ion source for generating an ion beam from a plasma chamber;
b) an analyzing superconducting magnet for modifying the beam to have a prescribed charge to mass ratio;
c) a defecting superconducting magnet for causing the beam to repetitively scan side to side at a prescribed frequency range;
d) a parallelizing superconducting magnet for ensuring that the beam is substantially parallel across a workpiece surface; and
e) an implantation chamber positioned along the beam path subsequent to the superconducting magnets for implanting ions on a workpiece surface, said superconducting magnets comprising:
i) a core made from a plurality of magnet laminations;
ii) a plurality of coils made from superconducting materials;
iii) a current source for energizing the superconducting magnets; and
iv) a cooling system for cooling the superconducting magnets and maintaining said coils' superconducting materials at a superconducting temperature
f) wherein the superconducting magnet maintains the current through the superconducting coil within predetermined ranges for analyzing, deflecting, or parallelizing the ion beam upon a workpiece.

23. The ion implantation system of claim 22, wherein said superconducting materials are made from a low T_{C} material.

24. The ion implantation system of claim 22, wherein said superconducting materials are made from a high T_{C} material.

25. The ion implantation system of claim 23, wherein said low T_{C} material is made from NbTi.

26. The ion implantation system of claim 24, wherein said high T_{C} material is made from Bi₂Sr₂CaCu₂O₈.

27. The ion implantation system of claim 24, wherein said high T_{C} material is made from MgB₂.

28. The ion implantation system of claim 24, wherein said high T_{C} material is selected from a group comprising MgB₂ and Bi₂Sr₂CaCu₂O₈.
